(19) United States
(12) Patent Application Publication
(10) Pub. No.: US 2025/0218832 A1
(43) Pub. Date: Jul. 3, 2025

(54) SUBSTRATE PROCESSING APPARATUS, SUBSTRATE PROCESSING METHOD, METHOD OF MANUFACTURING SEMICONDUCTOR DEVICE, NON-TRANSITORY COMPUTER-READABLE RECORDING MEDIUM AND SUBSTRATE RETAINER ASSEMBLY

(71) Applicant: Kokusai Electric Corporation, Tokyo (JP)

(72) Inventors: Tatsuya NISHINO, Toyama (JP); Yukinori ABURATANI, Toyama (JP)

(21) Appl. No.: 18/980,942

(22) Filed: Dec. 13, 2024

(30) Foreign Application Priority Data
Dec. 28, 2023 (JP) 2023-223026

(51) Int. Cl. H01L 21/673; H01L 21/687

(52) U.S. Cl. CPC H01L 21/67309; H01L 21/68742; H01L 21/6875; H01L 21/68771

(57) ABSTRACT

It is possible to prevent the substrate from sticking to the substrate support when forming the film. There is provided a technique that includes: a primary boat provided with first support structures; a process vessel; second support structures vertically movable; a rotator provided with a rotation shaft; and a driver for lifting one or more substrates apart from the first support structures by elevating the second support structures upward. The driver includes: a linear motion shaft; a transmission structure for transmitting a linear motion of the linear motion shaft to the second support structures; and an actuator for lifting a lower surface of the linear motion shaft in the axial direction. The actuator and the lower surface of the linear motion shaft are spaced apart from each other when an upward force is not applied by the actuator onto the lower surface of the linear motion shaft.

### CROSS REFERENCE TO RELATED APPLICATIONS

This non-provisional U.S. patent application is based on and claims priority under 35 U.S.C. § 119(a)-(d) of Japanese Patent Application No. 2023-223026 filed on Dec. 28, 2023, in the Japanese Patent Office, the entire contents of which are hereby incorporated by reference.

### TECHNICAL FIELD

The present disclosure relates to a substrate processing apparatus, a substrate processing method, a method of manufacturing a semiconductor device, a non-transitory computer-readable recording medium and a substrate retainer assembly.

### BACKGROUND

According to some related arts, among substrate processing apparatuses serving as semiconductor manufacturing apparatuses configured to process a semiconductor substrate (also referred to as a “substrate” or a “wafer”), a substrate processing apparatus may be used to perform a film forming process by placing a boat (which serves as a substrate support in which a large number of semiconductor substrates are accommodated) inside a vertical type process furnace of the substrate processing apparatus.

When forming a film (which is thick) on the substrate, the film may be formed in the vicinity of a contact portion between the substrate and the substrate support. In such a case, the substrate may stick to the substrate support, and as a result, particles may be generated when the substrate stuck to the substrate support is removed (or taken out) from the substrate support.

### SUMMARY

According to the present disclosure, there is provided a technique capable of preventing a substrate from sticking to a substrate support when forming a film. Other objects and novel features of the technique of the present disclosure will become apparent from the description of the present specification and the accompanying drawings.

The following is a brief overview of a representative one of embodiments of the technique of the present disclosure.

According to an embodiment of the present disclosure, there is provided a technique that includes: a primary boat provided with a plurality of first support structures, wherein at least one first support structure among the plurality of first support structures is provided for each of a plurality of substrates; a process vessel in which the primary boat is accommodated, wherein the plurality of substrates supported by the primary boat are processed in the process vessel; a plurality of second support structures provided to be movable in a vertical direction relative to the primary boat; a rotator provided with a rotation shaft configured to rotatably support the primary boat; and a driver configured to be capable of lifting at least one among the plurality of substrates apart from at least one among the plurality of first support structures by elevating the plurality of second support structures upward relative to the primary boat, wherein the driver includes: a linear motion shaft configured to be capable of linearly moving in an axial direction of the rotation shaft; a transmission structure configured to be capable of transmitting a linear motion of the linear motion shaft to the plurality of second support structures; and an actuator configured to be capable of lifting a lower surface of the linear motion shaft in the axial direction by applying an upward force onto lower surface of the linear motion shaft, and wherein the actuator and the lower surface of the linear motion shaft are spaced apart from each other when the upward force is not applied by the actuator onto the lower surface of the linear motion shaft.

### BRIEF DESCRIPTION OF THE DRAWINGS

FIG. 1 is a diagram schematically illustrating a vertical cross-section of a vertical type process furnace (also simply referred to as a “process furnace”) 202 of a substrate processing apparatus preferably used in one or more embodiments of the present disclosure.

FIG. 2 is a diagram schematically illustrating a horizontal cross-section, taken along a line A-A shown in FIG. 1, of the process furnace 202 of the substrate processing apparatus preferably used in the embodiments of the present disclosure.

FIG. 3 is a diagram schematically illustrating a perspective view of a primary boat 217a preferably used in the embodiments of the present disclosure.

FIG. 4 is a diagram schematically illustrating a perspective view of a secondary boat 217b preferably used in the embodiments of the present disclosure.

FIG. 5 is a diagram schematically illustrating horizontal cross-sections of the primary boat 217a and the secondary boat 217b preferably used in the embodiments of the present disclosure.

FIG. 6 is a diagram schematically illustrating a vertical cross-section in the vicinity of a bottom plate of a boat preferably used in the embodiments of the present disclosure, and more specifically, a central cross-section in the vicinity of a rotation shaft.

FIG. 7 is a diagram schematically illustrating a cross-section of an actuator preferably used in the embodiments of the present disclosure.

FIG. 8 is a block diagram schematically illustrating a configuration of a controller 121 and related components of the substrate processing apparatus preferably used in the embodiments of the present disclosure.

FIG. 9 is a flow chart schematically illustrating a process flow of a substrate processing according to the embodiments of the present disclosure.

### DETAILED DESCRIPTION

Hereinafter, one or more embodiments (also simply referred to as “embodiments”) of the technique of the present disclosure will be described in detail mainly with reference to the drawings. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

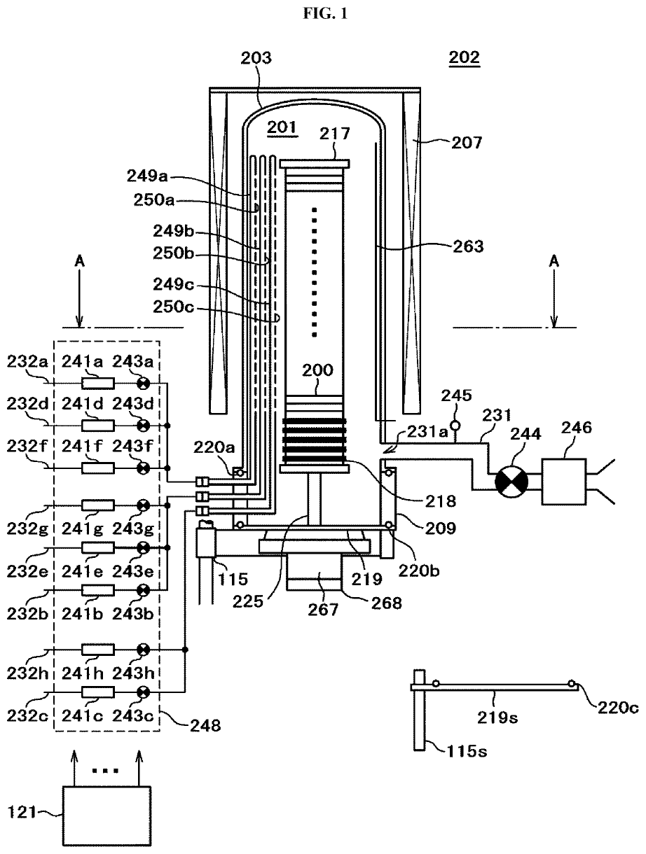

As shown in FIG. 1, a substrate processing apparatus according to the present embodiments includes a process furnace 202. The process furnace 202 includes a heater 207 serving as a temperature regulator (which is a temperature adjusting structure or a heating structure). The heater 207 is of a cylindrical shape, and is vertically installed while being supported by a support plate (not shown). The heater 207 also functions as an activator (also referred to as an “exciter”) capable of activating (or exciting) a gas by a heat.

A reaction tube 203 is provided in an inner side of the heater 207 to be aligned in a manner concentric with the heater 207. For example, the reaction tube 203 is made of a heat resistant material such as quartz (SiO₂) and silicon carbide (SiC). For example, the reaction tube 203 is of a cylindrical shape with a closed upper end and an open lower end. A manifold 209 is provided under the reaction tube 203 to be aligned in a manner concentric with the reaction tube 203. For example, the manifold 209 is made of a metal material such as stainless steel (SUS). For example, the manifold 209 is of a cylindrical shape with open upper and lower ends. An upper end portion of the manifold 209 is engaged with a lower end portion of the reaction tube 203 so as to support the reaction tube 203. An O-ring 220a serving as a seal is provided between the manifold 209 and the reaction tube 203. Similar to the heater 207, the reaction tube 203 is installed vertically. A process vessel (also referred to as a “reaction vessel”) is constituted mainly by the reaction tube 203 and the manifold 209. A process chamber 201 is provided in a hollow cylindrical portion of the process vessel. The process chamber 201 is configured to be capable of accommodating a plurality of wafers including a wafer 200 serving as a substrate. Hereinafter, the plurality of wafers including the wafer 200 may also be simply referred to as “wafers 200”. The wafer 200 is processed in the process chamber 201.

Nozzles 249a, 249b and 249c are provided in the process chamber 201 so as to penetrate a side wall of the manifold 209. The nozzle 249a serves as a first supplier (which is a first supply structure), the nozzle 249b serves as a second supplier (which is a second supply structure) and the nozzle 249c serves as a third supplier (which is a third supply structure). The nozzles 249a, 249b and 249c may also be referred to as a “first nozzle 249a”, a “second nozzle 249b” and a “third nozzle 249c”, respectively. For example, each of the nozzles 249a, 249b and 249c is made of a heat resistant material such as quartz and silicon carbide (SiC). Gas supply pipes 232a, 232b and 232c are connected to the nozzles 249a, 249b and 249c, respectively. The nozzles 249a, 249b and 249c are different nozzles. The nozzles 249a and 249c are provided adjacent to the nozzle 249b such that the nozzle 249b is interposed between the nozzles 249a and 249c.

Mass flow controllers (also simply referred to as “MFCs”) 241a, 241b and 241c serving as flow rate controllers (flow rate control structures) and valves 243a, 243b and 243c serving as opening/closing valves are sequentially installed at the gas supply pipes 232a, 232b and 232c, respectively, in this order from upstream sides to downstream sides of the gas supply pipes 232a, 232b and 232c in a gas flow direction. Gas supply pipes 232d and 232f are connected to the gas supply pipe 232a at a downstream side of the valve 243a of the gas supply pipe 232a. Gas supply pipes 232e and 232g are connected to the gas supply pipe 232b at a downstream side of the valve 243b of the gas supply pipe 232b. A gas supply pipe 232h is connected to the gas supply pipe 232c at a downstream side of the valve 243c of the gas supply pipe 232c. MFCs 241d, 241e, 241f, 241g and 241h and valves 243d, 243e, 243f, 243g and 243h are sequentially installed at the gas supply pipes 232d, 232e, 232f, 232g and 232h, respectively, in this order from upstream sides to downstream sides of the gas supply pipes 232d, 232e, 232f, 232g and 232h in the gas flow direction. For example, each of the gas supply pipes 232a to 232h is made of a metal material such as SUS.

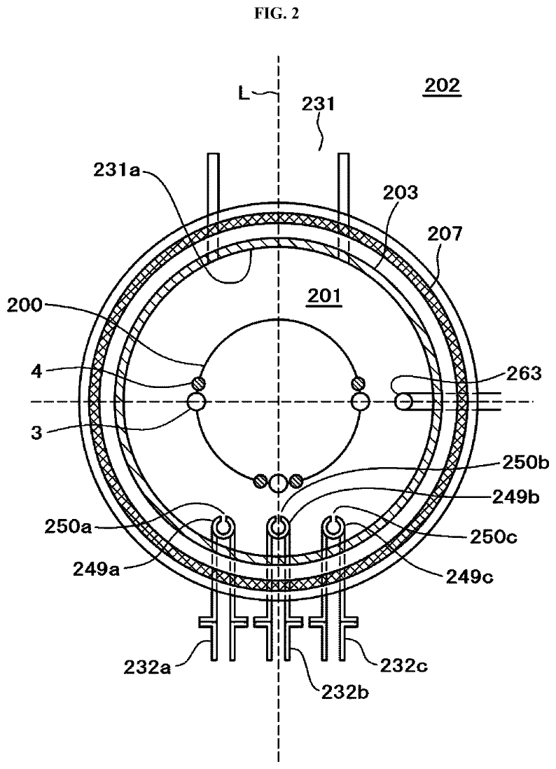

As shown in FIG. 2, each of the nozzles 249a to 249c is installed in an annular space provided between an inner wall of the reaction tube 203 and the wafers 200 when viewed from above, and extends upward from a lower portion toward an upper portion of the reaction tube 203 along the inner wall of the reaction tube 203 (that is, extends upward along an arrangement direction of the wafers 200). That is, each of the nozzles 249a to 249c is installed in a region that is located beside and horizontally surrounds a wafer arrangement region in which the wafers 200 are arranged (stacked) along the wafer arrangement region. When viewed from above, the nozzle 249b is arranged so as to face an exhaust port 231a described later along a straight line (denoted by “L” shown in FIG. 2) with a center of the wafer 200 transferred (loaded) into the process chamber 201 interposed therebetween. The nozzles 249a and 249c are arranged along the inner wall of the reaction tube 203 (that is, along an outer periphery of the wafer 200) such that the straight line L passing through the nozzle 249b and a center of the exhaust port 231a is interposed therebetween. The straight line L may also be referred to as a straight line passing through the nozzle 249b and the center of the wafer 200. That is, it can be said that the nozzle 249c is provided opposite to the nozzle 249a with the straight line L interposed therebetween. The nozzles 249a and 249c are arranged line-symmetrically (that is, in a line symmetry) with respect to the straight line L serving as an axis of symmetry. A plurality of gas supply holes 250a, a plurality of gas supply holes 250b and a plurality of gas supply holes 250c are provided at side surfaces of the nozzles 249a, 249b and 249c, respectively. Gases can be supplied via the gas supply holes 250a, the gas supply holes 250b and the gas supply holes 250c, respectively. The gas supply holes 250a, the gas supply holes 250b and the gas supply holes 250c are open toward the exhaust port 231a when viewed from above, and are configured such that the gases are supplied toward the wafers 200 via the gas supply holes 250a, the gas supply holes 250b and the gas supply holes 250c, respectively. The gas supply holes 250a, the gas supply holes 250b and the gas supply holes 250c are provided from the lower portion toward the upper portion of the reaction tube 203.

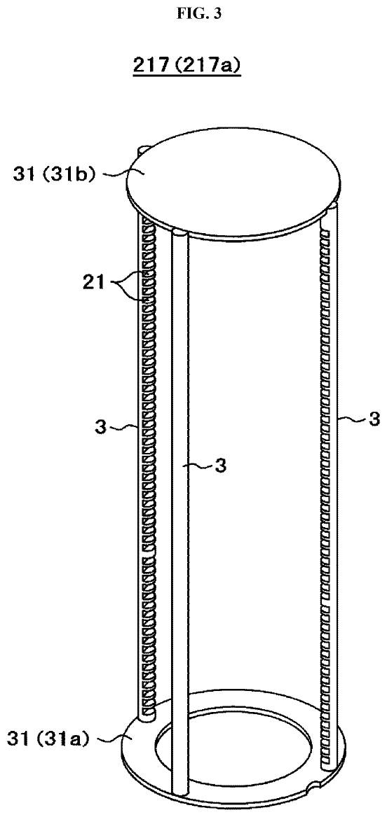

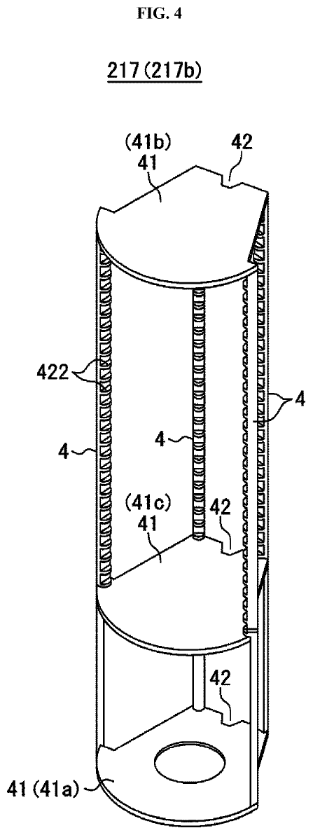

As shown in FIGS. 3 and 4, at outer peripheries of the wafers 200, a plurality of fixed support columns 3 of a primary boat 217a and a plurality of movable support columns 4 of a secondary boat 217b are provided.

An etching gas is supplied into the process chamber 201 through the gas supply pipe 232a provided with the MFC 241a and the valve 243a and the nozzle 249a. As the etching gas, for example, a fluorine (F)-containing gas (hereinafter, also referred to as an “F-containing gas”) may be used.

A reducing gas is supplied into the process chamber 201 through the gas supply pipe 232b provided with the MFC 241b and the valve 243b and the nozzle 249b. As the reducing gas, for example, a hydrogen (H)-containing gas (hereinafter, also referred to as an “H-containing gas”) may be used.

A second process gas (which serves as one of source gases) is supplied into the process chamber 201 through the gas supply pipe 232c provided with the MFC 241c and the valve 243c and the nozzle 249c. As the second process gas, for example, a gas containing a Group 14 element such as germanium (Ge) may be used. Hereinafter, a gas containing germanium may also be referred to as a “Ge-containing gas”.

A first process gas (which serves as one of the source gases) is supplied into the process chamber 201 through the gas supply pipe 232d provided with the MFC 241d and the valve 243d, the gas supply pipe 232a and the nozzle 249a. As the first process gas, for example, a gas containing a Group 14 element such as silicon (Si) may be used. Hereinafter, a gas containing silicon may also be referred to as a “Si-containing gas”.

A dopant gas is supplied into the process chamber 201 through the gas supply pipe 232e provided with the MFC 241e and the valve 243e, the gas supply pipe 232b and the nozzle 249b.

An inert gas is supplied into the process chamber 201 via the gas supply pipes 232f to 232h provided with the MFCs 241f to 241h and the valves 243f to 243h, respectively, the gas supply pipes 232a to 232c and the nozzles 249a to 249c. For example, the inert gas may act as a purge gas, a carrier gas, a dilution gas and the like.

An etching gas supplier (which is an etching gas supply structure or an etching gas supply system) is constituted mainly by the gas supply pipe 232a, the MFC 241a and the valve 243a. A reducing gas supplier (which is a reducing gas supply structure or a reducing gas supply system) is constituted mainly by the gas supply pipe 232b, the MFC 241b and the valve 243b. A second process gas supplier (which is a second process gas supply structure or a second process gas supply system) is constituted mainly by the gas supply pipe 232c, the MFC 241c and the valve 243c. The second process gas supplier may also be referred to as a “Ge-containing gas supplier” (which is a Ge-containing gas supply structure or a Ge-containing gas supply system). A first process gas supplier (which is a first process gas supply structure or a first process gas supply system) is constituted mainly by the gas supply pipe 232d, the MFC 241d and the valve 243d. The first process gas supplier may also be referred to as a “Si-containing gas supplier” (which is a Si-containing gas supply structure or a Si-containing gas supply system). A dopant gas supplier (which is a dopant gas supply structure or a dopant gas supply system) is constituted mainly by the gas supply pipe 232e, the MFC 241e and the valve 243e. Further, an inert gas supplier (which is an inert gas supply structure or an inert gas supply system) is constituted mainly by the gas supply pipes 232f to 232h, the MFCs 241f to 241h and the valves 243f to 243h. Further, any one or the entirety of the gas suppliers mentioned above may be embodied as an integrated gas supply system 248 in which the components such as the valves 243a to 243h and the MFCs 241a to 241h are integrated.

The exhaust port 231a through which an inner atmosphere of the process chamber 201 is exhausted is provided at a lower side wall of the reaction tube 203. As shown in FIG. 2, the exhaust port 231a is arranged at a location so as to face the nozzles 249a to 249c (the gas supply holes 250a to the gas supply holes 250c) with the wafer 200 interposed therebetween when viewed from above. The exhaust port 231a may be provided so as to extend upward from the lower portion toward the upper portion of the reaction tube 203 along a side wall of the reaction tube 203 (that is, along the wafer arrangement region). An exhaust pipe 231 is connected to the exhaust port 231a. A vacuum pump 246 serving as a vacuum exhaust apparatus is connected to the exhaust pipe 231 through a pressure sensor 245 and an APC (Automatic Pressure Controller) valve 244. The pressure sensor 245 serves as a pressure detector (pressure detection structure) configured to detect an inner pressure of the process chamber 201, and the APC valve 244 serves as a pressure regulator (pressure adjusting structure). With the vacuum pump 246 in operation, the APC valve 244 may be opened or closed to perform a vacuum exhaust operation for the process chamber 201 or stop the vacuum exhaust operation. With the vacuum pump 246 in operation, the inner pressure of the process chamber 201 may be adjusted by adjusting an opening degree of the APC valve 244 based on pressure information detected by the pressure sensor 245. An exhauster (which is an exhaust structure or an exhaust system) is constituted mainly by the exhaust pipe 231, the APC valve 244 and the pressure sensor 245. The exhauster may further include the vacuum pump 246.

A seal cap 219 serving as a furnace opening lid capable of airtightly sealing (or closing) a lower end opening of the manifold 209 is provided under the manifold 209. For example, the seal cap 219 is made of a metal material such as SUS, and is of a disk shape. An O-ring 220b serving as a seal is provided on an upper surface of the seal cap 219 so as to be in contact with the lower end of the manifold 209. A rotator (which is a rotating structure) 267 configured to rotate a boat 217 (that is, the primary boat 217a and the secondary boat 217b) described later is provided under the seal cap 219. For example, a rotation shaft 225 of the rotator 267 penetrates the seal cap 219, and is connected to the boat 217 through the seal cap 219. As the rotator 267 rotates the boat 217, the wafers 200 accommodated in the boat 217 are rotated. The rotator 267 and seal cap 219 is elevated or lowered in the vertical direction by a boat elevator 115 serving as an elevator arm (elevating structure) provided outside the reaction tube 203. That is, the boat elevator 115 serving as the elevator arm can drive the rotator 267 and the lid (seal cap 219) up and down. The boat elevator 115 serves as a transfer apparatus (which is a transfer structure or a transfer system) capable of transferring (loading) the boat 217 and the wafers 200 accommodated therein into the process chamber 201 and capable of transferring (unloading) the boat 217 and the wafers 200 accommodated therein out of the process chamber 201 by elevating and lowering the seal cap 219.

Further, a driver 268 serving as a driving structure is provided below the seal cap 219. The driver 268 is used to simultaneously elevate the wafers 200 in the boat 217 in the process chamber 201 during a film forming process described later.

A shutter 219s serving as a furnace opening lid capable of airtightly sealing (or closing) the lower end opening of the manifold 209 is provided under the manifold 209. The shutter 219s is configured to close the lower end opening of the manifold 209 when the seal cap 219 is lowered by the boat elevator 115 and the boat 217 is unloaded out of the process chamber 201. For example, the shutter 219s is made of a metal material such as SUS, and is of a disk shape. An O-ring 220c serving as a seal is provided on an upper surface of the shutter 219s so as to be in contact with the lower end of the manifold 209. An opening and closing operation, an elevation operation and a rotation operation of the shutter 219s is controlled by a shutter opener/closer (which is a shutter opening/closing structure) 115s.

The boat 217 serving as a substrate support (substrate retainer) may be constituted by the primary boat 217a shown in FIG. 3 and the secondary boat 217b shown in FIG. 4, and the primary boat 217a and the secondary boat 217b are combined. Hereinafter, the primary boat 217a may also be simply referred to as a “boat 217a”.

The primary boat 217a includes a plurality of first support structures 21. The first support structures 21 are configured such that the wafers 200 (for example, 25 wafers to 200 wafers) are accommodated (or supported) in the vertical direction in the primary boat 217a while the wafers 200 are horizontally oriented with their centers aligned with one another in a multistage manner with a predetermined interval therebetween. That is, the primary boat 217a is configured such that one or more of the first support structures 21 can be provided for each of the substrates (wafers), that is, at least one for a single substrate (wafer). For example, the primary boat 217a is made of a heat resistant material such as quartz and SiC. For example, a plurality of heat insulation plates 218 made of a heat resistant material such as quartz and SiC are supported at a lower portion of the primary boat 217a in a multistage manner as shown in FIG. 1.

As shown in FIG. 3, the primary boat 217a includes: the fixed support columns 3 (three fixed support columns in an example shown in FIG. 3) extending in a direction substantially perpendicular to the wafer 200 and each provided with the first support structures 21; and a first coupler 31 configured to fix (or couple) the fixed support columns 3 to one another. Further, the first coupler 31 includes: a first bottom plate 31a configured to fix the fixed support columns 3 to one another in the vicinity of lower ends of the fixed support columns 3; and a first top plate 31b configured to fix the fixed support columns 3 to one another in the vicinity of upper ends of the fixed support columns 3. Each of the fixed support columns 3 is provided with the first support structures 21. The primary boat 217a is accommodated in the process vessel (process chamber 201), and the wafers (substrates) 200 supported by the primary boat 217a are processed in the process vessel (process chamber 201).

The secondary boat 217b includes a plurality of second support structures 422. The second support structures 422 are configured such that the wafers 200 (for example, 25 wafers to 200 wafers) are accommodated (or supported) in the vertical direction in the secondary boat 217b while the wafers 200 are horizontally oriented with their centers aligned with one another in a multistage manner with a predetermined interval therebetween. The second support structures 422 are provided so as to be movable in the vertical direction (up-down direction) relative to the primary boat 217a. For example, the secondary boat 217b is made of a heat resistant material such as quartz and SiC.

As shown in FIG. 4, the secondary boat 217b includes: the movable support columns 4 (four movable support columns in an example shown in FIG. 4) extending in the direction substantially perpendicular to the wafer 200 and each provided with the second support structures 422; and a second coupler 41 configured to fix (or couple) the movable support columns 4 to one another. Further, the second coupler 41 includes: a second bottom plate 41a configured to fix the movable support columns 4 to one another in the vicinity of lower ends of the movable support columns 4; a second top plate 41b configured to fix the movable support columns 4 to one another in the vicinity of upper ends of the movable support columns 4; and a middle plate 41c configured to fix the movable support columns 4 at a portion in the middle of the movable support columns 4 (that is, a portion between the upper and lower ends of each of the movable support columns 4). Each of the movable support columns 4 is provided with the second support structures 422. The second top plate 41b and the second bottom plate 41a of the secondary boat 217b are configured to be capable of being fitted between the first top plate 31b and the first bottom plate 31a of the primary boat 217a. As shown in FIG. 2, the movable support columns 4 are arranged in a manner capable of being separated from and contacted by the driver 268 such that the movable support columns 4 can be rotated together with the primary boat 217a on the outer peripheries of the wafers (substrates) 200 supported by the primary boat 217a.

The second bottom plate 41a is a plate whose shape is configured such that the plate can be stably placed on the first bottom plate 31a. A notch 42 is provided on one side of each of the second bottom plate 41a, the second top plate 41b and the middle plate 41c. One of the fixed support columns 3 is inserted into the notch 42. In other words, the secondary boat 217b is provided with the movable support columns 4 where the second support structures 422 are installed, respectively, and the second coupler 41 configured to fix the movable support columns 4 to one another. The secondary boat 217b is installed such that the secondary boat 217b can move up and down relative to the primary boat 217a within a range whose upper and lower limits are restricted.

According to the present embodiments, when the number of the movable support columns 4 is N (where N is an integer equal to or greater than 3), the number of the fixed support columns 3 is (N−1) or (N+1). In such a case, the second bottom plate 41a is configured as a plate with at least N vertices, and the movable support columns 4 are configured to be connected to the second bottom plate 41a in a manner corresponding to the N vertices, respectively. In addition, the first support structures 21 of the fixed support columns 3 are located (provided) closer to the center of the wafer (substrate) 200 than the second support structures 422.

The driver 268 is configured to elevate the second support structures 422 relatively upward to move up the wafer (substrate) 200 apart from at least one among the first support structures 21. Specifically, in a configuration in which the primary boat 217a and the secondary boat 217b are combined, as described above, the secondary boat 217b can move up and down relative to the primary boat 217a within the range whose upper and lower limits are restricted. Then, during the film forming process, the driver 268 moves the secondary boat 217b upward relative to the primary boat 217a within the range whose upper and lower limits are restricted such that the wafers 200 are elevated simultaneously.

When forming a film (which is thick) on the wafer 200, the film may also be formed on the boat 217 (which serves as the substrate support) itself depending on the film thickness. As a result, the wafer 200 may stick to the boat 217, and thereby particles may be generated. In order to reduce a generation of such particles, the following method may be considered. According to the method, when the film of a certain thickness is to be formed, the boat 217 is removed from the process furnace 202, the wafers 200 are elevated one by one in a transfer chamber by a transport apparatus (which is a transport structure) and returned to original positions thereof, and the boat 217 is loaded again into the process furnace 202 to form the film (which is thick) on the wafer 200. However, according to such a method, a film forming time may be increased, a quality of the film may deteriorate due to an oxidation, and a thermal history may become non-uniform. However, according to the present embodiments, by elevating the wafers 200 in the process chamber 201 of the process vessel, it is possible to shorten the film forming time and also possible to improve the quality of the film. Further, since an operation of simultaneously elevating the wafers 200 is performed under a reduced pressure in the process furnace 202 (that is, in the process chamber 201 of the process vessel), it is possible to dramatically improve the throughput. In addition, since the substrate support (boat 217) is not moved to the transfer chamber, it is possible to suppress the oxidation in the transfer chamber, and it is possible to reduce the thermal history of the wafer 200 caused by picking up the wafer 200 with tweezers. Thereby, it is possible to improve the quality of the film. Further, the transfer chamber is in an atmospheric atmosphere or a nitrogen (N₂) atmosphere with an oxygen (O₂) concentration of 20 ppm or less. In addition, since a back surface (rear surface) of the wafer 200 is exposed in the process chamber 201 of the process vessel, the film is formed on both of a front surface and the back surface (rear surface) of the wafer 200. Thereby, it is possible to prevent the wafer 200 from warping.

A temperature sensor 263 serving as a temperature detector is installed in the reaction tube 203. A state of electric conduction to the heater 207 is adjusted based on temperature information detected by the temperature sensor 263 such that a desired temperature distribution of an inner temperature of the process chamber 201 can be obtained. The temperature sensor 263 is provided along the inner wall of the reaction tube 203.

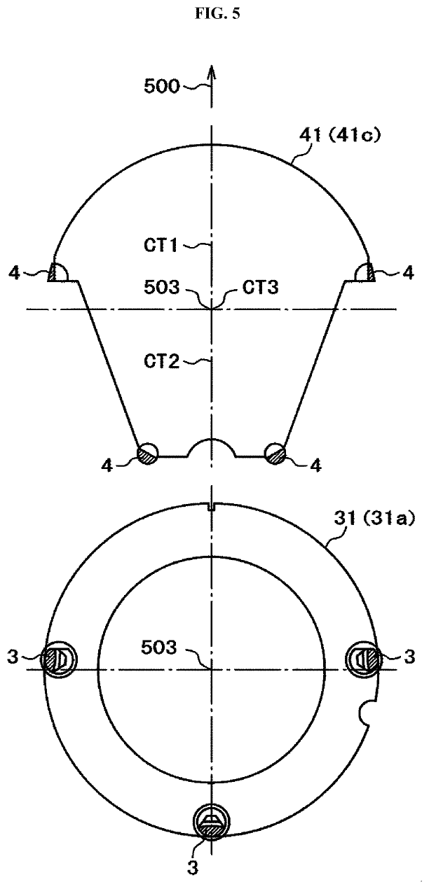

In FIG. 5, a horizontal cross-section of the primary boat 217a is shown in a lower region of FIG. 5, and a horizontal cross-section of the secondary boat 217b is shown in an upper region of FIG. 5. In FIG. 5, the primary boat 217a and the secondary boat 217b are shown together such that a center of the primary boat 217a in a left-right direction coincides with a center of the secondary boat 217b in the left-right direction. In the secondary boat 217b, a center of gravity CT1 of the second coupler 41 (41a, 41b and 41c) itself is shifted away from a rotation center shaft 503 toward a substrate unloading direction (that is, a direction of unloading the wafers 200) 500. In addition, in the secondary boat 217b, a center of gravity CT2 of the four movable support columns 4 is biased toward a side opposite to the substrate unloading direction 500. A center of gravity CT3 of the entirety of the secondary boat 217b is almost on the rotation center shaft 503.

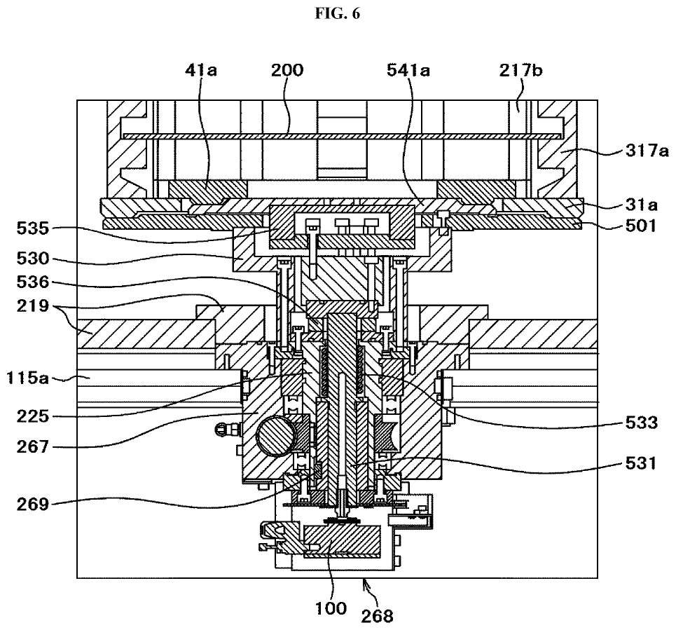

A configuration of the driver 268 and a secondary boat placement stage 541a will be described with reference to FIG. 6.

FIG. 6 is a diagram schematically illustrating vertical cross-sections of an elevator arm 115a of the boat elevator 115, a boat stage 501 on which the first bottom plate 31a is placed, the secondary boat placement stage 541a on which the second bottom plate 41a is placed, and the driver 268 (shown in FIG. 1) provided below the secondary boat placement stage 541a. In the present specification, a substrate retainer assembly is defined as a configuration that collectively includes the boat 217 (the primary boat 217a and the secondary boat 217b), the rotator 267 and the driver 268.

At the elevator arm 115a, the rotator 267 provided with the rotation shaft 225 configured to rotatably support the primary boat 217a is installed. A rotation shaft coupler 530 is connected to the rotation shaft 225. The rotation shaft coupler 530 penetrates the seal cap 219, and is connected to a back surface of the boat stage 501 through the seal cap 219. The rotation shaft coupler 530 provided on the rotation shaft 225 is configured to rotatably support the boat stage 501. The rotation shaft coupler 530 is fixed to the boat stage 501 of a disk shape, and the boat stage 501 supports the primary boat 217a and the secondary boat 217b thereon. For example, the boat stage 501 is made of a metal material such as SUS, and is of a disk shape. On the boat stage 501, the secondary boat placement stage 541a (to which the second bottom plate 41a of a disk shape is fixed) and the first bottom plate 31a (of a ring shape and provided around the secondary boat placement stage 541a) are placed.

The driver 268 includes an actuator 100, a linear motion shaft 531, a linear ball guide 533 and a transmission structure 535. The linear motion shaft 531 is arranged to be capable of linearly moving in an axial direction of a rotation center of the rotation shaft 225 (in a manner corresponding to the rotation center shaft 503 in FIG. 5), and is configured such that a linear motion thereof is controlled by controlling the actuator 100. Further, the center of gravity CT3 of the secondary boat 217b is located directly above the linear motion shaft 531.

The rotation shaft 225 is provided with a cavity penetrating in the axial direction, and the linear motion shaft 531 is disposed within the cavity of the rotation shaft 225. The linear ball guide 533 serves as a guide configured to support the linear motion shaft 531 such that the linear motion shaft 531 can move only in the axial direction relative to the rotation shaft 225. The transmission structure 535 is configured to be capable of transmitting the linear motion of the linear motion shaft 531 to the second support structures 422 of the secondary boat 217b. For example, it is preferable that the transmission structure 535 is screw-fixed to the second bottom plate 41a and the linear motion shaft 531.

The driver 268 further includes a bellows 536. The bellows 536 is configured to connect the linear motion shaft 531 and the rotation shaft 225, and is further configured to isolate a cavity in the rotation shaft 531 and the linear ball guide 533 from the process vessel. A reference numeral 269 indicates a connection key configured to synchronously rotate the linear motion shaft 531 and the rotation shaft 225.

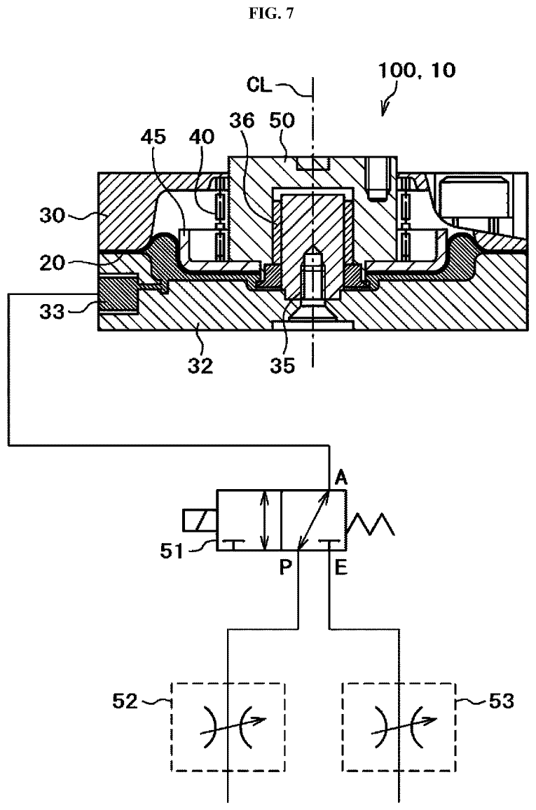

A rod 50 of the actuator 100 (see FIG. 7 described later) is configured to be capable of lifting a lower surface of the linear motion shaft 531 in the axial direction by applying an upward force onto the lower surface of the linear motion shaft 531. When the upward force is not applied by the rod 50 of the actuator 100 onto the lower surface of the linear motion shaft 531, the rod 50 of the actuator 100 and the lower surface of the linear motion shaft 531 are spaced apart from each other. When the upward force is not applied by the rod 50 of the actuator 100 onto the lower surface of the linear motion shaft 531, the second bottom plate 41a of the second coupler 41 is placed on the first bottom plate 31a of the first coupler 31.

Subsequently, an exemplary configuration of the actuator 100 will be described with reference to FIG. 7.

As shown in FIG. 7, the actuator 100 includes a diaphragm cylinder 10, and is provided with a diaphragm 20, an upper housing 30, a lower housing 32, a guide 35, a coil spring 40, a piston 45 and the rod 50 (an example of a shaft structure). The diaphragm cylinder 10 is provided with a function of moving the rod 50 back and forth within a specified range by deforming the diaphragm 20 with a working fluid such as air.

The diaphragm 20 is configured as a deformable rectangular structure made of a rubber with an opening in a center thereof, and is located such that a surface thereof is perpendicular to a direction of a movement of the rod 50 (a direction along an axis marked with a symbol CL in FIG. 7). Further, a circular step is provided at the diaphragm 20 in advance such that the diaphragm 20 can be easily deformed in a direction perpendicular to the surface thereof.

The upper housing 30 and the lower housing 32 are configured as metal structures provided with walls around a plate with a contour corresponding to the diaphragm 20. A box-shaped housing is provided by fixing the upper housing 30 and the lower housing 32 such that the walls face each other and are fixed while an outer edge of the diaphragm 20 is disposed therebetween. An opening is provided in a center of the upper housing 30, and a space between the upper housing 30 and the diaphragm 20 communicates with the outside. On the other hand, the lower housing 32 is provided with an air supply port 33 serving as only a single port configured to communicate with a space (also referred to as a “pressurized space”) between the lower housing 32 and the diaphragm 20.

The guide 35 is configured as a cylinder-shaped structure extending from a center of the lower housing 32 toward the upper housing 30 along the axis CL. The guide 35 is provided with a bearing 36 at its portion engaging with the rod 50, and is configured to guide the movement of the rod 50 on the axis CL. For example, the bearing 36 is configured as a sliding bearing (bushing).

The piston 45 is configured as a disk-shaped structure with a curved periphery, and is provided such that a lower surface of the piston 45 contacts with the diaphragm 20, in a state where the guide 35 penetrates an opening provided in a center of the piston 45. The upper housing 30 receives a pressure of the working fluid through the diaphragm 20 and transmits the pressure to the rod 50. The opening of the piston 45 and the opening of the diaphragm 20 are airtightly connected.

The rod 50 is configured as a cylinder-shaped structure with a closed end. More specifically, the bearing 36 is connected to an inner peripheral surface of the rod 50, the opening of the piston 45 is airtightly connected to a lower end of the rod 50, and an upper end (that is, the closed end) of the rod 50 is exposed from the opening of the upper housing 30. An inner space of the rod 50 serves as only a single space capable of communicating with the pressurized space. However, the inner space of the rod 50 does not communicate with the outside. As a result, a substance such as friction powder and oil mist from the bearing 36 does not scatter into the transfer chamber.

The coil spring 40 is disposed between an upper surface of the piston 45 and a lower surface of the upper housing 30, and applies a pressure onto the piston 45 downward along the axis CL, that is, in a direction opposite to a direction in which a cylinder (that is, the diaphragm cylinder 10) is pushed by the pressure of the working fluid. With such a configuration, the diaphragm cylinder 10 functions as a single-acting cylinder configured to push the rod 50 out from the air supply port 33 with the pressure of the working fluid, and configured to retract the rod 50 with the force of the coil spring 40 when the working fluid is not supplied. By driving the diaphragm cylinder 10 in a single-acting manner as described above, it is possible to reduce a risk of a working fluid leakage as compared with a case where other types of cylinders are used.

### Operation of Diaphragm Cylinder

A configuration and operation for supplying the working fluid to the air supply port 33 of the diaphragm cylinder 10 will be described. A solenoid valve 51 is configured as a 3-way universal solenoid valve, and is provided with a pressurized port (P port), an exhaust port (E port) and an A port. The A port is in a bidirectional fluid communication with the E port when not energized, and in a bidirectional fluid communication with the P port when energized. The A port is connected to the air supply port 33 of the diaphragm cylinder 10, the P port is connected to a compressed air supply source such as a compressor, and the E port is connected to an exhaust duct.

A speed controller 52 is a of a throttle valve whose opening is capable of being adjusted, and is provided between the P port and the compressed air supply source to restrict (or limit) a flow rate of the working fluid injected into the diaphragm cylinder 10. Thereby, it is possible to adjust a speed (also referred to as an “extrusion speed”) at which the rod 50 is pushed out.

A speed controller 53 is a valve similar to the speed controller 52, and is provided between the E port and the exhaust duct to restrict the flow rate of the working fluid discharged from the diaphragm cylinder 10. Thereby, it is possible to adjust a speed (also referred to as a “retracting speed”) at which the rod 50 is retracted. When it is unnecessary for the retracting speed and the extrusion speed to be independently adjusted, the speed controller 52 alone may be provided between the A port and the air supply port 33.

For example, it is preferable to move the diaphragm cylinder 10 or the rod 50 upward or downward by setting a maximum of a pushing-up or pushing-down speed of the rod 50 to be 10 mm/s or less.

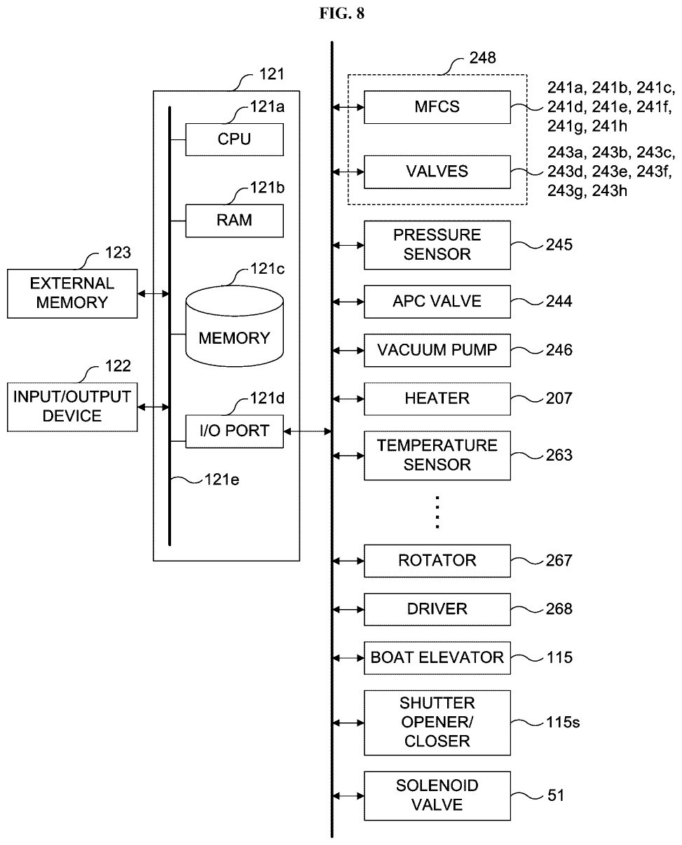

As shown in FIG. 8, a controller 121 serving as a control structure (control apparatus) is constituted by a computer including a CPU (Central Processing Unit) 121a, a RAM (Random Access Memory) 121b, a memory 121c and an I/O port (input/output port) 121d. The RAM 121b, the memory 121c and the I/O port 121d may exchange data with the CPU 121a through an internal bus 121e. For example, an input/output device 122 constituted by a component such as a touch panel is connected to the controller 121. Further, the controller 121 is configured to be capable of being connected to an external memory 123.

For example, the memory 121c is configured by a component such as a flash memory, a hard disk drive (HDD) and a solid state drive (SSD). For example, a control program configured to control an operation of the substrate processing apparatus and a process recipe containing information on procedures and conditions of a substrate processing described later may be readably stored in the memory 121c. The process recipe is obtained by combining steps (procedures and conditions) of the substrate processing described later such that the controller 121 can execute the steps to acquire a predetermined result, and functions as a program. Hereinafter, the process recipe and the control program may be collectively or individually referred to as a “program”. In addition, the process recipe may also be simply referred to as a “recipe”. Thus, in the present specification, the term “program” may refer to the recipe alone, may refer to the control program alone or may refer to both of the recipe and the control program. The RAM 121b functions as a memory area (work area) where a program or data read by the CPU 121a is temporarily stored.

The I/O port 121d is connected to the components described above such as the MFCs 241a to 241h, the valves 243a to 243h, the pressure sensor 245, the APC valve 244, the vacuum pump 246, the temperature sensor 263, the heater 207, the rotator 267, the boat elevator 115, the shutter opener/closer 115s and the solenoid valve 51.

The CPU 121a is configured to read the control program from the memory 121c and execute the read control program. In addition, the CPU 121a is configured to read the recipe from the memory 121c, for example, in accordance with an operation command inputted from the input/output device 122. In accordance with contents of the read recipe, the CPU 121a may be configured to be capable of controlling various operations such as flow rate adjusting operations for various substances (various gases) by the MFCs 241a to 241h, opening and closing operations of the valves 243a to 243h, an opening and closing operation of the APC valve 244, a pressure regulating operation (pressure adjusting operation) by the APC valve 244 based on the pressure sensor 245, a start and stop operation of the vacuum pump 246, a temperature regulating operation (temperature adjusting operation) by the heater 207 based on the temperature sensor 263, an operation of adjusting a rotation and a rotation speed of the boat 217 by the rotator 267, an operation of moving the secondary boat 217b up and down by the driver 268, an elevating and lowering operation of the boat 217 by the boat elevator 115, an opening and closing operation of the shutter 219s by the shutter opener/closer 115s and an opening and closing operation of the solenoid valve 51.

The controller 121 may be embodied by installing the above-described program stored in the external memory 123 into the computer. For example, the external memory 123 may include a magnetic disk such as the HDD, an optical disk such as a CD, a magneto-optical disk such as an MO and a semiconductor memory such as a USB memory and the SSD. The memory 121c or the external memory 123 may be embodied by a non-transitory computer readable recording medium. Hereafter, the memory 121c and the external memory 123 may be collectively or individually referred to as a “recording medium”. Thus, in the present specification, the term “recording medium” may refer to the memory 121c alone, may refer to the external memory 123 alone, or may refer to both of the memory 121c and the external memory 123. Instead of the external memory 123, a communication interface such as the Internet and a dedicated line may be used for providing the program to the computer.

The controller 121 is configured to be capable of controlling components constituting the substrate processing apparatus described above to perform:
a step a (or a procedure a) of placing the plurality of wafers 200 on the primary boat 217a provided with the plurality of first support structures 21 and accommodating the plurality of wafers 200 in the process chamber 201 of the process vessel, wherein at least one first support structure among the plurality of first support structures 21 is provided for each of the plurality of wafers 200;
a step b (or a procedure b) of processing the plurality of wafers 200 in the process chamber 201 of the process vessel while the rotator 267 provided with the rotation shaft 225 configured to support the boat 217 (that is, the primary boat 217a and the secondary boat 217b) rotates the boat 217 (the primary boat 217a and the secondary boat 217b) by supplying the gas through the gas supplier (that is, the gas supply pipe 232d, the MFC 241d, the valve 243d, the gas supply pipe 232a and the nozzle 249a) while rotating the boat 217 (the primary boat 217a and the secondary boat 217b); and
a step c (or a procedure c) of lifting at least one among the plurality of wafers 200 apart from at least one among the plurality of first support structures 21 by elevating the plurality of second support structures 422 relatively upward by the driver 268 while maintaining the plurality of wafers 200 in the process chamber 201 of the process vessel, wherein the plurality of second support structures 422 are provided to be movable in the vertical direction relative to the boat 217 (the primary boat 217a and the secondary boat 217b) to separate the plurality of wafers 200 from the plurality of first support structures 21 sequentially or simultaneously.

The controller 121 is further configured to be capable of controlling the components constituting the substrate processing apparatus described above to perform the step a to the step c a predetermined number of times to form a film whose thickness is equal to or greater than a predetermined thickness on the wafers 200. In the step c, the driver 268 is used. The driver 268 includes: the linear motion shaft 531 configured to be capable of linearly moving in the axial direction of the rotation shaft 225; the transmission structure 535 configured to be capable of transmitting the linear motion of the linear motion shaft 531 to the plurality of second support structures 422; and the actuator 100 configured to be capable of lifting the lower surface of the linear motion shaft 531 in the axial direction by applying an upward force onto the lower surface of the linear motion shaft 531. Further, in the step b, the actuator 100 and the lower surface of the linear motion shaft 531 are spaced apart from each other. The controller 121 is further configured to be capable of controlling the rotator 267 to stop the rotation of the boat 217 (the primary boat 217a and the secondary boat 217b).

### (2) Substrate Processing

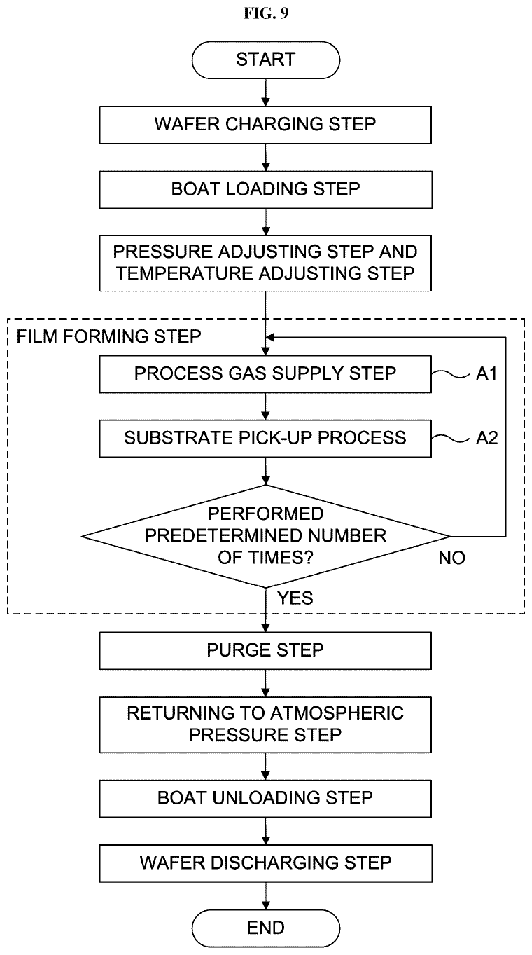

Hereinafter, an example of a process sequence (that is, a film forming sequence) of the substrate processing of forming a film on the surface of the wafer 200 serving as the substrate by using the substrate processing apparatus mentioned above will be described with reference to FIG. 9. The film forming sequence is performed as a substrate processing method, which is a part of a method of manufacturing a semiconductor device. In the following descriptions, operations of the components constituting the substrate processing apparatus are controlled by the controller 121.

In the present specification, the term “wafer” may refer to “a wafer itself”, or may refer to “a wafer and a stacked structure (aggregated structure) of a predetermined layer (or layers) or a film (or films) formed on a surface of the wafer”. In the present specification, the term “a surface of a wafer” may refer to “a surface of a wafer itself”, or may refer to “a surface of a predetermined layer (or a predetermined film) formed on a wafer”. Thus, in the present specification, “forming a predetermined layer (or a film) on a wafer” may refer to “forming a predetermined layer (or a film) directly on a surface of a wafer itself”, or may refer to “forming a predetermined layer (or a film) on a surface of another layer (or another film) formed on a wafer”. In the present specification, the terms “substrate” and “wafer” may be used as substantially the same meaning. Further, in the present specification, a notation of a numerical range such as “from 1 Pa to 2,000 Pa” means that a lower limit and an upper limit are included in the numerical range. Therefore, for example, a numerical range “from 1 Pa to 2,000 Pa” means a range equal to or higher than 1 Pa and equal to or lower than 2,000 Pa. The same also applies to other numerical ranges described in the present specification. Furthermore, when it is described that a supply flow rate includes 0 slm, it means that material (gas) is not supplied at all. That applies also to the following descriptions. Further, in the present specification, the term “process temperature” may refer to a temperature of the wafer 200 or the inner temperature of the process chamber 201, and the term “process pressure” may refer to the inner pressure of the process chamber 201. In addition, the term “process time” may refer to a time (time duration) during which a process related thereto is performed. The same also applies to the following descriptions.

### Wafer Charging Step and Boat Loading Step

The wafers 200 are charged (transferred) into the boat 217 (wafer charging step). Then, the shutter 219s is moved by the shutter opener/closer 115s to open the lower end opening of the manifold 209 (shutter opening step). Thereafter, as shown in FIG. 1, the boat 217 supporting the wafers 200 is elevated by the boat elevator 115 and loaded (transferred) into the process chamber 201 (boat loading step). With the boat 217 loaded, the seal cap 219 airtightly seals the lower end of the manifold 209 via the O-ring 220b. In a manner described above, the wafers 200 are loaded into the process chamber 201.

### Pressure Adjusting Step and Temperature Adjusting Step

After the boat loading step is completed, the vacuum pump 246 vacuum-exhausts (decompresses and exhausts) the inner atmosphere of the process chamber 201 (that is, a space in which the wafers 200 are present (accommodated)) such that the inner pressure of the process chamber 201 reaches and is maintained at a desired pressure (vacuum degree). When the vacuum pump 246 vacuum-exhausts the inner atmosphere of the process chamber 201, the inner pressure of the process chamber 201 is measured by the pressure sensor 245, and the APC valve 244 is feedback-controlled based on the pressure information detected by the pressure sensor 245 (pressure adjusting step). In addition, the heater 207 heats the process chamber 201 such that a temperature of the wafer 200 in the process chamber 201 reaches and is maintained at a desired process temperature (which is a first temperature). When the heater 207 heats the process chamber 201, the state of the electric conduction to the heater 207 is feedback-controlled based on the temperature information detected by the temperature sensor 263 such that a desired temperature distribution of the inner temperature of the process chamber 201 can be obtained (temperature adjusting step). In addition, a rotation of the wafer 200 is started by the rotator 267. The vacuum pump 246 continuously vacuum-exhausts the inner atmosphere of the process chamber 201, the heater 207 continuously heats the wafer 200 in the process chamber 201 and the rotator 267 continuously rotates the wafer 200 until at least a processing of the wafer 200 is completed.

### Film Forming Step (A1, A2)

### Step A1: Process Gas Supply Step

In a step Al, while the wafer 200 is heated to a predetermined temperature, at least one among the first process gas and the second process gas is supplied to the wafer 200 to perform the film forming process of growing the film on the surface of the wafer 200.

When depositing a silicon germanium film (SiGe film), the second process gas is supplied into the gas supply pipe 232c. A flow rate of the second process gas is adjusted by the MFC 241c, and the second process gas whose flow rate is adjusted is supplied into the process chamber 201 through the gas supply pipe 232c and the nozzle 249c. In such a state, the valve 243d is opened to supply the first process gas into the gas supply pipe 232d. A flow rate of the first process gas is adjusted by the MFC 241d, and the first process gas whose flow rate is adjusted is supplied into the process chamber 201 through the gas supply pipe 232a and the nozzle 249a, and is exhausted through the exhaust port 231a together with the second process gas. In the present step, the first process gas and the second process gas are supplied to the wafer 200 through edge (side portion) of the wafer 200. In the present step, the valves 243f to 243h may be opened to supply the inert gas into the process chamber 201 through each of the nozzles 249a to 249c.

For example, process conditions in the step A1 are as follows:
The process temperature (predetermined temperature): from 500° C. to 650° C., more preferably from 550° C. to 600° C.;
The process pressure: from 1 Pa to 200 Pa, more preferably from 4 Pa to 120 Pa;
A supply flow rate of the first process gas: from 0.1 slm to 5 slm, more preferably 0.2 slm to 3 slm;
A supply flow rate of the second process gas: from 0.1 slm to 5 slm, more preferably 0.2 slm to 3 slm;
A supply flow rate of the inert gas (for each gas supply pipe): from 0 slm to 20 slm, more preferably from 0.1 slm to 10 slm; and
A gas supply time (time duration): from 20 minutes to 60 hours, more preferably from 30 minutes to 360 minutes.

By supplying the first process gas and the second process gas to the wafer 200 in accordance with the process conditions described above, it is possible to form an epitaxial film (for example, an epitaxial SiGe film containing a predetermined element) on the surface of the wafer 200. When the first process gas alone is supplied as the source gas, it is possible to form a silicon film (Si film).

After the step A1 is completed, the valves 243a and 243c are closed to stop a supply of the first process gas and a supply of the second process gas into the process chamber 201.

### Step A2: Substrate Pick-Up Process

After the step A1, the driver 268 moves the secondary boat 217b relatively upward, and thereby, the wafers 200 are simultaneously elevated from the primary boat 217a. After a certain time has elapsed, the driver 268 moves the secondary boat 217b relatively downward, and thereby, the wafers 200 are simultaneously placed on the primary boat 217a. During the step A2, the rotation of the boat 217 (that is, the primary boat 217a and the secondary boat 217b) is stopped.

### Performing Cycle Predetermined Number of Times

A cycle of alternately performing the step A1 and the step A2 mentioned above is repeatedly performed a predetermined number of times (n times, where n is an integer of 1 or more).

### Purge Step

After the film forming step is completed, the inert gas serving as the purge gas is supplied into the process chamber 201 through each of the nozzles 249a, 249b and 249c, and then is exhausted through the exhaust port 231a. Thereby, the inside of the process chamber 201 is purged with the purge gas. As a result, a substance such as a gas remaining in the process chamber 201 and reaction by-products remaining in the process chamber 201 are removed from the process chamber 201 (after-purge step). Thereafter, the inner atmosphere of the process chamber 201 is replaced with the inert gas (substitution by inert gas), and the inner pressure of the process chamber 201 is returned to the normal pressure (atmospheric pressure) (returning to atmospheric pressure step).

### Boat Unloading Step and Wafer Discharging Step

Thereafter, the seal cap 219 is lowered by the boat elevator 115 and the lower end of the manifold 209 is opened. Then, the boat 217 with the wafers 200 (which are processed and supported in the boat 217) is unloaded (transferred) out of the reaction tube 203 through the lower end of the manifold 209 (boat unloading step). After the boat 217 is unloaded, the shutter 219s is moved such that the lower end opening of the manifold 209 is sealed by the shutter 219s through the O-ring 220c (shutter closing step). Then, the wafers 200 (which are processed) are discharged (transferred) from the boat 217 unloaded out of the reaction tube 203 (wafer discharging step).

### Modified Example

Hereinafter, a modified example of a fixing method of the secondary boat 217b to the secondary boat placement stage 541a will be described. The secondary boat 217b may be fixed to the secondary boat placement stage 541a using a component such as screw, instead of just being placed on the secondary boat placement stage 541a. Further, even when the secondary boat 217b is not fixed, the second bottom plate 41a of the secondary boat 217b is configured to hook onto heads of quartz screws configured to secure the primary boat 217a to the boat stage (primary boat stage) 501. Thus, for example, even when an earthquake occurs, the secondary boat 217b will not fall off the primary boat 217a. According to the modified example, it is possible to obtain substantially the same effects as those of the present embodiments.

According to the present embodiments, it is possible to obtain one or more of the following effects.
1) During the film forming process, the secondary boat 217b (which is a pick-up boat) is elevated in the process chamber 201, and thereby, the wafers 200 are elevated up and separated from the primary boat 217a such that an adhesion between the primary boat 217a and the wafers 200 can be broken. Thereafter, the wafers 200 are lowered back into the primary boat 217a in the process chamber 201, and the film forming process can be resumed.
2) When the boat 217 is being rotated by the rotator 267, the rotator 267 is separated from the driver 268. Therefore, the rotator 267 may not be aligned with the driver 268. In addition, no load or heat is transmitted to the driver 268, so an overload or vibration due to a misalignment does not occur. Thereby, it is possible to lengthen a life of the driver 268.
3) Since an inclination of the secondary boat 217b or the vibrations associated therewith are reduced, a positional deviation or the like of the substrate (wafer 200) is unlikely to occur.
4) The secondary boat 217b is elevated at one point on the rotation center shaft of the secondary boat 217b by the transmission structure 535 of a sufficient thickness that is close to the center of gravity of the secondary boat 217b. Thereby, it is possible to stably move the secondary boat 217b up and down.
5) By using the diaphragm cylinder 10 as the actuator 100, it is possible to operate the actuator 100 smoothly at a low speed. Further, there is no air leakage into the transfer chamber where the air is replaced with an N₂ atmosphere. Further, a heat resistance is set to 100° C., which is higher than that of a motor. In addition, it is possible to lengthen a life of the actuator 100.

While the technique of the present disclosure is described in detail by way of the embodiments mentioned above, the technique of the present disclosure is not limited thereto. The technique of the present disclosure may be modified in various ways without departing from the scope thereof. The technique of the present disclosure is not limited to a vertical type substrate processing apparatus. However, the technique of the present disclosure may be preferably applied when a single wafer type substrate processing apparatus or a multi wafer type substrate processing apparatus is used. That is, the embodiments mentioned above are described by way of an example in which the batch type substrate processing apparatus capable of simultaneously processing a plurality of substrates is used to form the film. However, the technique of the present disclosure is not limited thereto. For example, the technique of the present disclosure may be preferably applied when the single wafer type substrate processing apparatus (or the multi wafer type substrate processing apparatus) capable of simultaneously processing one substrate (or several substrates) is used to form the film. For example, the embodiments mentioned above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film. The process procedures and the process conditions of each process using the substrate processing apparatuses exemplified above may be substantially the same as those of the embodiments or the modified example mentioned above. Even in such a case, it is possible to obtain substantially the same effects as in the embodiments or the modified example mentioned above. Further, the embodiments or the modified example mentioned above may be appropriately combined. The process procedures and the process conditions of each combination thereof may be substantially the same as those of the embodiments or the modified example mentioned above.

According to some embodiments of the present disclosure, it is possible to prevent the substrate from sticking to the substrate support when forming the film.

What is claimed is:

1. A substrate processing apparatus comprising:
a primary boat provided with a plurality of first support structures, wherein at least one first support structure among the plurality of first support structures is provided for each of a plurality of substrates;
a process vessel in which the primary boat is accommodated, wherein the plurality of substrates supported by the primary boat are processed in the process vessel;
a plurality of second support structures provided to be movable in a vertical direction relative to the primary boat;
a rotator provided with a rotation shaft configured to rotatably support the primary boat; and
a driver configured to be capable of lifting at least one among the plurality of substrates apart from at least one among the plurality of first support structures by elevating the plurality of second support structures upward relative to the primary boat,
wherein the driver comprises:
a linear motion shaft configured to be capable of linearly moving in an axial direction of the rotation shaft;
a transmission structure configured to be capable of transmitting a linear motion of the linear motion shaft to the plurality of second support structures; and
an actuator configured to be capable of lifting a lower surface of the linear motion shaft in the axial direction by applying an upward force onto lower surface of the linear motion shaft, and
wherein the actuator and the lower surface of the linear motion shaft are spaced apart from each other when the upward force is not applied by the actuator onto the lower surface of the linear motion shaft.

2. The substrate processing apparatus of claim 1, wherein the plurality of second support structures are connected to one another by a second coupler to form a secondary boat, and
wherein a center of gravity of the secondary boat is located directly above the linear motion shaft.

3. The substrate processing apparatus of claim 2, wherein the primary boat is provided with:
a plurality of fixed support columns extending in a direction substantially perpendicular to the plurality of substrates and each provided with the plurality of first support structures; and
a first coupler configured to fix the plurality of fixed support columns to one another,
wherein the secondary boat is provided with a plurality of movable support columns extending in the direction substantially perpendicular to the plurality of substrates and each provided with the plurality of second support structures, and
wherein the first coupler is provided with a first bottom plate configured to fix the plurality of fixed support columns to one another in the vicinity of lower ends of the plurality of fixed support columns, and the second coupler is provided with a second bottom plate configured to fix the plurality of movable support columns to one another in the vicinity of lower ends of the plurality of movable support columns and further configured to be coupled to the transmission structure.

4. The substrate processing apparatus of claim 3, wherein the number of the plurality of movable support columns is set to N (where N is an integer equal to or greater than 3), the number of the plurality of fixed support columns is set to (N−1) or (N+1), the second bottom plate is configured as a plate with at least N vertices, and the plurality of movable support columns are connected to the second bottom plate in a manner corresponding to the N vertices, respectively.

5. The substrate processing apparatus of claim 3, wherein the second coupler is placed on the first coupler when the upward force is not applied by the actuator onto the lower surface of the linear motion shaft.

6. The substrate processing apparatus of claim 3, wherein the transmission structure is screw-fixed to the second bottom plate and the linear motion shaft.

7. The substrate processing apparatus of claim 2, wherein a center of gravity of the second coupler itself is shifted away from the rotation shaft toward a direction of unloading the plurality of substrates.

8. The substrate processing apparatus of claim 1, wherein the rotation shaft is provided with a cavity penetrating in the axial direction, and the linear motion shaft is disposed within the cavity of the rotation shaft.

9. The substrate processing apparatus of claim 8, further comprising:
a guide configured to support the linear motion shaft such that the linear motion shaft is capable of moving only in the axial direction relative to the rotation shaft.

10. The substrate processing apparatus of claim 9, further comprising:
a bellows configured to connect the linear motion shaft with the rotation shaft and isolate the cavity in the rotation shaft and the guide from the process vessel.

11. The substrate processing apparatus of claim 8, wherein the actuator comprises a diaphragm cylinder, and
wherein the diaphragm cylinder is moved with a maximum speed of 10 mm/s or less by restricting a flow rate of a working fluid by a speed controller.

12. A substrate processing method comprising:
(a) placing a plurality of substrates on a primary boat provided with a plurality of first support structures and accommodating the plurality of substrates in a process vessel, wherein at least one first support structure among the plurality of first support structures is provided for each of the plurality of substrates;
(b) processing the plurality of substrates in the process vessel while a rotator provided with a rotation shaft configured to support the primary boat rotates the primary boat; and
(c) lifting at least one among the plurality of substrates apart from at least one among the plurality of first support structures by elevating a plurality of second support structures upward relative to the primary boat, wherein the plurality of second support structures are provided to be movable in a vertical direction relative to the primary boat,
wherein a driver is used in (c), the driver comprising:
a linear motion shaft configured to be capable of linearly moving in an axial direction of the rotation shaft;
a transmission structure configured to be capable of transmitting a linear motion of the linear motion shaft to the plurality of second support structures; and
an actuator configured to be capable of lifting a lower surface of the linear motion shaft in the axial direction by applying an upward force onto the lower surface of the linear motion shaft, and
wherein the actuator and the lower surface of the linear motion shaft are spaced apart from each other in (b).

13. A method of manufacturing a semiconductor device, comprising:
the method of claim 12.

14. The method of claim 13, wherein (b) and (c) are repeatedly performed, and a rotation of the primary boat is stopped during (c).

15. A non-transitory computer-readable recording medium storing a program that causes a substrate processing apparatus, by a computer, to perform the method of claim 12.

16. A substrate retainer assembly, comprising:
a primary boat configured to be capable of accommodating a plurality of substrates in a process vessel while the plurality of substrates are arranged in a vertical direction, and provided with a plurality of first support structures, wherein at least one first support structure among the plurality of first support structures is provided for each of the plurality of substrates;
a plurality of second support structures provided to be movable in the vertical direction relative to the primary boat;
a rotator provided with a rotation shaft configured to rotatably support the primary boat; and
a driver configured to be capable of lifting at least one among the plurality of substrates apart from at least one among the plurality of first support structures by elevating the plurality of second support structures upward relative to the primary boat,
wherein the driver comprises:
a linear motion shaft configured to be capable of linearly moving in an axial direction of the rotation shaft;
a transmission structure configured to be capable of transmitting a linear motion of the linear motion shaft to the plurality of second support structures; and
an actuator configured to be capable of lifting a lower surface of the linear motion shaft in the axial direction by applying an upward force onto the lower surface of the linear motion shaft, and
wherein the actuator and the lower surface of the linear motion shaft are spaced apart from each other when the upward force is not applied by the actuator onto the lower surface of the linear motion shaft.
